(19) United States
(12) Patent Application Publication
(10) Pub. No.: US 2013/0244437 A1
(43) Pub. Date: Sep. 19, 2013

(54) METHODS OF FORMING FEATURES ON AN INTEGRATED CIRCUIT PRODUCT USING A NOVEL COMPOUND SIDEWALL IMAGE TRANSFER TECHNIQUE

(71) Applicants: Stefan Flachowsky, Dresden (DE); Ralf Illgen, Dresden (DE); Thilo Scheiper, Dresden (DE)

(72) Inventors: Stefan Flachowsky, Dresden (DE); Ralf Illgen, Dresden (DE); Thilo Scheiper, Dresden (DE)

(73) Assignee: GLOBALFOUNDRIES INC., Grand Cayman (KY)

(21) Appl. No.: 13/421,069

(22) Filed: Mar. 15, 2012

(51) Int. Cl. H01L 21/311

(52) U.S. Cl. 438/703; 257/E21.249

(57) ABSTRACT

One illustrative method disclosed herein includes forming a sacrificial mandrel above a structure, forming a plurality of first sidewall spacers on opposite sides of the sacrificial mandrel, removing the sacrificial mandrel, forming a plurality of second sidewall spacers on opposite sides of each of the first sidewall spacers, and removing the first sidewall spacers to thereby define a patterned spacer mask layer comprised of the plurality of second sidewall spacers.

### BACKGROUND OF THE INVENTION

1. Field of the Invention

Generally, the present disclosure relates to the manufacturing of sophisticated semiconductor devices, and, more specifically, to various methods of forming various structures and features on an integrated circuit product using a novel compound sidewall image transfer technique.

2. Description of the Related Art

The fabrication of advanced integrated circuits, such as CPU's, storage devices, ASIC's (application specific integrated circuits) and the like, requires the formation of a large number of structures, such as transistors, resistors, capacitors, conductive contacts, metal lines, etc., in a given chip area according to a specified circuit layout. A field effect transistor (FET) is a planar device, irrespective of whether an NMOS transistor or a PMOS transistor is considered, that typically includes doped source and drain regions that are formed in a semiconducting substrate that are separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

Numerous processing operations are performed in a very detailed sequence, or process flow, to form all of the structures and features of such integrated circuit devices, e.g., deposition processes, etching processes, heating processes, masking operations, etc. In general, the formation of integrated circuit devices involves, among other things, the formation of various layers of material and patterning or removing portions of those layers of material to define a desired structure, such as a gate electrode, a sidewall spacer, an opening in a layer of insulating material for a conductive contact, a trench in a substrate for an isolation structure, etc. Device designers have been very successful in improving the electrical performance capabilities of transistor devices, primarily by reducing the size of or “scaling” various components of the transistor, such as the gate length of the transistors. In fact, device dimensions on modern day transistors have been reduced to the point where direct patterning of such features is very difficult using existing 193 nm based photolithography tools and technology. That is, the feature size or so-called critical dimension of some structures is so small that it is beyond the resolution capability of some of the current day photolithography tools. Thus, device designers have employed various techniques to pattern very small features. One such technique is generally known as a sidewall image transfer technique.

FIGS. 1A-1E depict one illustrative example of a prior art sidewall image transfer technique. As shown in FIG. 1A, a mandrel 12 is formed above a structure 10, such as a semiconducting substrate. The mandrel 12 may be made of a variety of materials, e.g., amorphous silicon, polysilicon, etc. The size of the mandrel 12 may vary depending upon the particular application. The mandrel 12 may be formed by depositing and patterning a layer of mandrel material using known deposition, photolithography and etching tools and techniques. Next, as shown in FIG. 1B, a layer of spacer material 14 is conformably deposited above the mandrel 12 and the structure 10. The layer of spacer material 14 may be comprised of a variety of materials, such as, for example, silicon nitride, silicon dioxide, etc. As reflected in FIG. 1C, an anisotropic etching process is performed to define spacers 14A adjacent the mandrel 12. Then as shown in FIG. 1D, the mandrel 12 is removed by performing a selective etching process that leaves the spacers 14A to act as masks in a subsequent etching process that defines feature 18 in the structure 10, as depicted in FIG. 1E. However, existing sidewall image transfer techniques still do not provide designers with the capability of making the very small features of the scale that device designers desire for current and future generations of integrated circuit products.

The present disclosure is directed to various methods of forming various structures and features on an integrated circuit product using a novel compound sidewall image transfer technique.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming various structures and features on an integrated circuit product using a novel compound sidewall image transfer technique. One illustrative method disclosed herein includes forming a sacrificial mandrel above a structure, forming a plurality of first sidewall spacers on opposite sides of the sacrificial mandrel, removing the sacrificial mandrel, forming a plurality of second sidewall spacers on opposite sides of each of the first sidewall spacers and removing the first sidewall spacers to thereby define a patterned spacer mask layer comprised of the plurality of second sidewall spacers. In further embodiments, the method involves performing an etching process on the structure through the patterned spacer mask layer, wherein the structure may be any layer of material or a substrate, and wherein the patterned spacer mask layer may be used to define any type of feature, e.g., a line-type feature, a hole-type feature, an island-type feature, etc.

Another illustrative method disclosed herein includes forming first and second sacrificial mandrels above a structure, wherein the first and second sacrificial mandrels have a spacing corresponding to a pitch distance, and forming a plurality of first sidewall spacers on opposite sides of each of the first and second sacrificial mandrels, wherein the first sidewall spacers have a thickness that is equal to or less than one-half of the pitch distance. This illustrative embodiment also includes the steps of removing the first and second sacrificial mandrels, forming a plurality of second sidewall spacers on opposite sides of each of the first sidewall spacers, wherein the second sidewall spacers have a thickness that is equal to or less than one-quarter of the pitch distance, and removing the first sidewall spacers to thereby define a patterned spacer mask layer comprised of the plurality of second sidewall spacers. In further embodiments, this method involves performing an etching process on the structure through the patterned spacer mask layer, wherein the structure may be any layer of material or a substrate, and wherein the patterned spacer mask layer may be used to define any type of feature, e.g., a line-type feature, a hole-type feature, an island-type feature, etc.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1E depict one illustrative example of a prior art sidewall image transfer technique; and

FIG. 2A-2K depict various illustrative methods disclosed herein of forming various structures and features on an integrated circuit product using a novel compound sidewall image transfer technique.

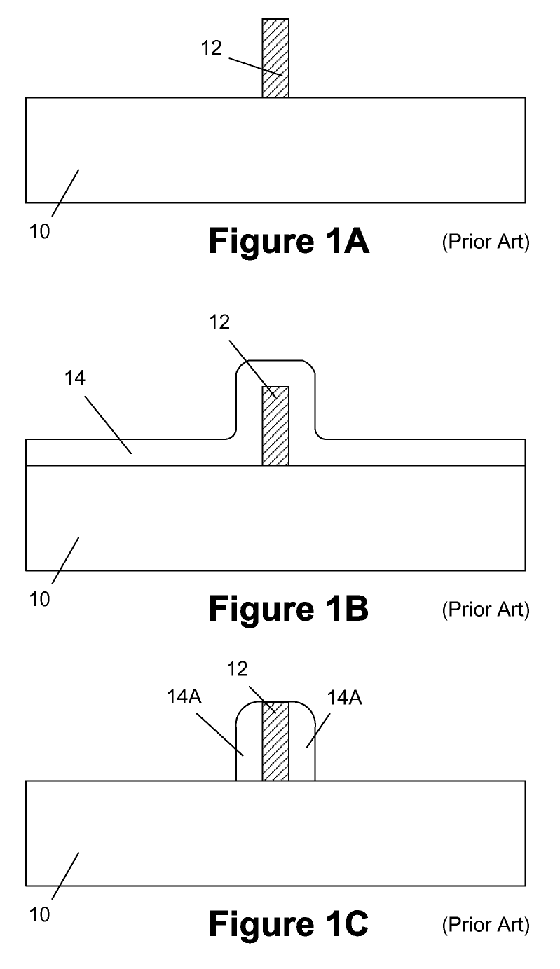

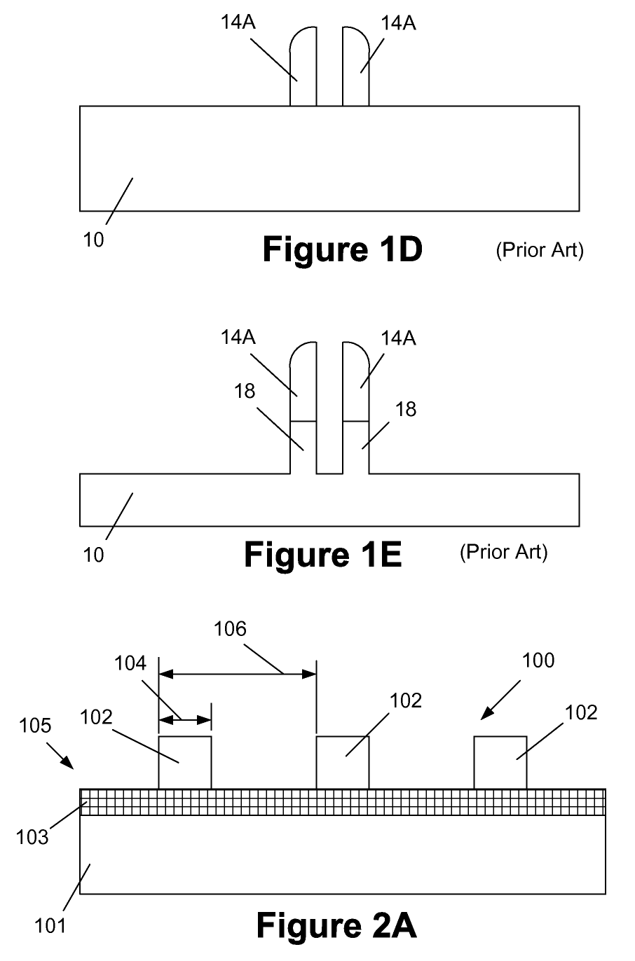

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming various structures and features on an integrated circuit product using a novel compound sidewall image transfer technique. As will be readily apparent to those skilled in the art upon a complete reading of the present application, the present method is applicable to a variety of technologies, e.g., NMOS, PMOS, CMOS, etc., and is readily applicable to a variety of devices, including, but not limited to, logic devices, memory devices, etc. In general, the various methods disclosed herein relate to the formation of a patterned spacer mask that is formed above a structure that may be used to perform an etching process on the structure through the patterned spacer mask layer to thereby transfer the pattern defined by the patterned spacer mask to the structure. As will be appreciated by those skilled in the art after a complete reading of the present application, the structure may be any layer of material or a substrate and the patterned spacer mask layer may be used to define any type of feature, e.g., a line-type feature, a hole-type feature, an island-type feature, etc., in such a structure. With reference to the attached drawings, various illustrative embodiments of the methods and devices disclosed herein will now be described in more detail.

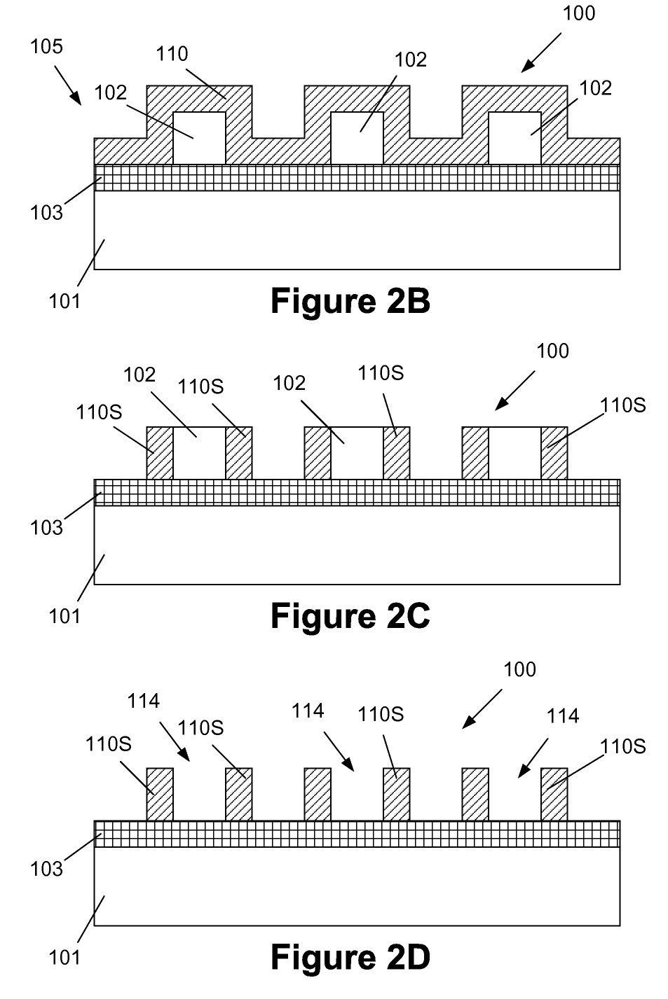

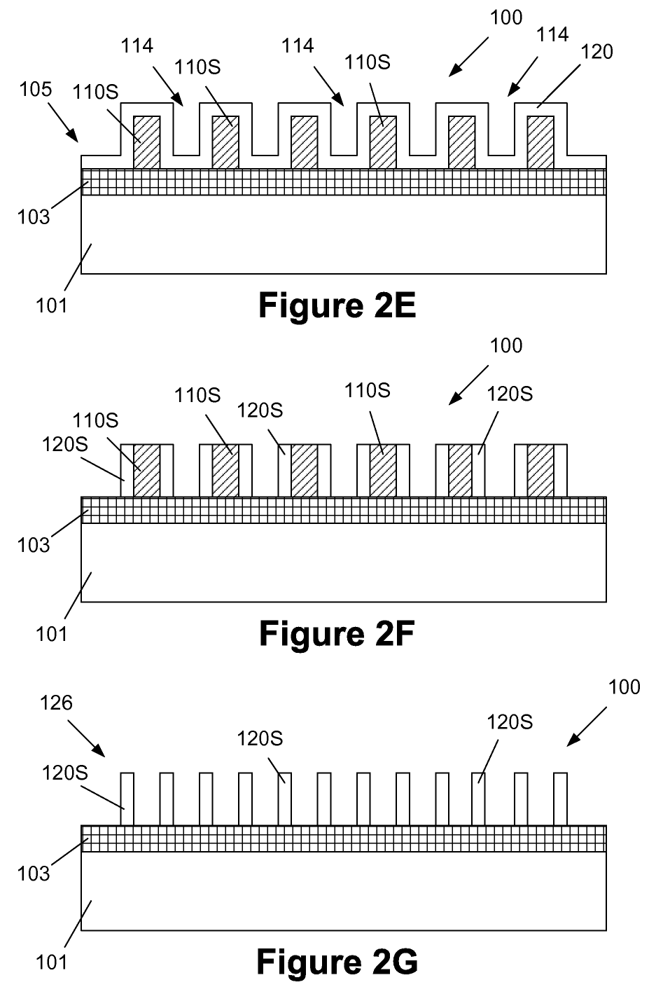

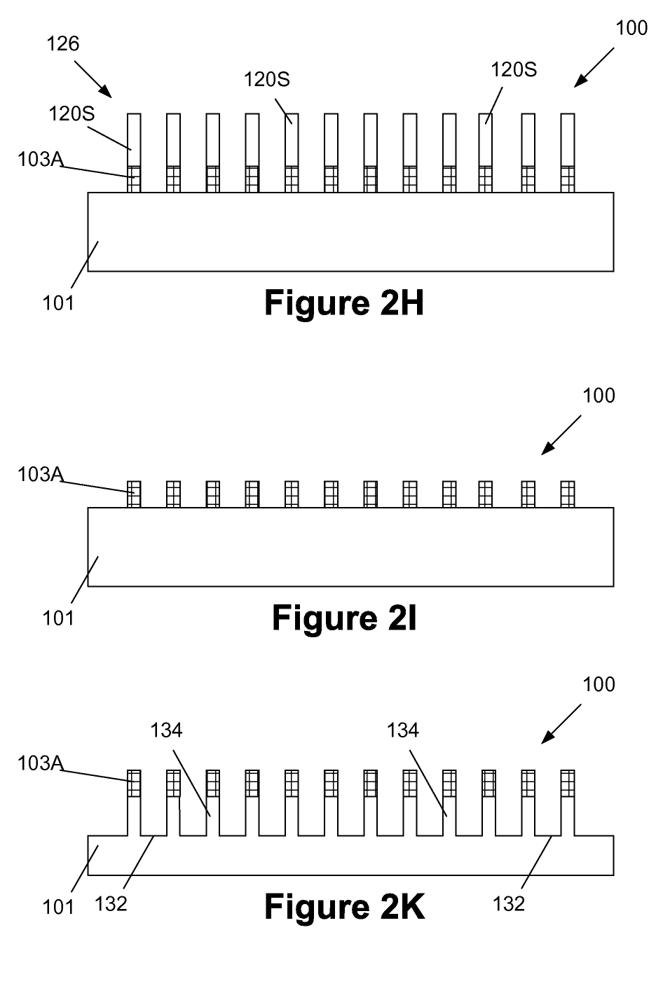

FIGS. 2A-2K depict various illustrative methods of forming various structures and features on an integrated circuit product using a novel compound sidewall image transfer technique. As shown in FIG. 2A, a plurality of sacrificial mandrels 102 are formed above a structure 105. In this illustrative embodiment, the structure 105 is comprised of a hard mask layer 103 that is formed above a semiconducting substrate 101, such as silicon, gallium arsenide, etc., and it may have either a bulk configuration or a so-called silicon-on-insulator (SOI) configuration. Of course, as mentioned above, the use of the patterned spacer mask layer (to be described more fully below) may be used in forming features in any type of layer of material (or multiple layers of material) or any type of substrate. For example, the item 101 could equally be a layer of insulating material, such as silicon dioxide, etc., wherein conductive metal lines and vias may be formed. Moreover, the pattern defined in the patterned spacer mask layer may correspond to any type of features, irrespective of their shape or configuration. Thus, the inventions disclosed herein should not be considered as limited to any of the particular examples depicted herein.

As to the example depicted in FIG. 2A, the semiconducting substrate 101 is a bulk silicon substrate. The hard mask layer 103 may be comprised of a variety of materials, such as, for example, silicon nitride, silicon oxynitride, etc. The hard mask layer 103 is not required in all applications, and the methods disclosed herein may be employed to transfer the pattern defined in the patterned spacer mask directly to an underlying layer of material or a substrate without using a hard mask layer. If employed, the hard mask layer 103 may be formed by performing a chemical vapor deposition (CVD) process, and it may have a thickness that varies depending upon the particular application, e.g., 20-50 nm. In some cases, if desired, a thin oxide layer (not shown) may be provided between the hard mask layer 103 and the substrate 101, e.g., when the hard mask layer is made of a material with a low etch selectivity relative to the substrate 101. Alternatively, the hard mask layer 103 may be made of a material that has a relatively high etch selectivity relative to the material of the substrate 101. The sacrificial mandrels 102 may be made of a variety of materials, e.g., amorphous silicon, polysilicon, silicon dioxide, etc. The sacrificial mandrels 102 may be formed by depositing and patterning a layer of mandrel material using known deposition, photolithography and etching tools and techniques. The methods disclosed herein involve, among other things, the formation of various sacrificial mandrels and spacers. In general, the mandrels and spacers should be made of materials that may be selectively etched with respect to one another. In one illustrative example, the pitch distance 106 between the sacrificial mandrels 102 may correspond to the lowest resolution capability of then existing photolithography tools. For example, in the case of 193 nm based photolithography tools that are commonly used in current day semiconductor manufacturing operations, the pitch distance 106 may be about 100 nm. Of course, as photolithography tools and techniques improve, the absolute value of the pitch distance may decrease over time. The width or critical dimension 104 of the sacrificial mandrels 102 may also vary depending upon the particular application. In one illustrative embodiment, the width 104 may be about 50-100 nm.

Next as shown in FIG. 2B, a first spacer material layer 110 is conformably deposited above the sacrificial mandrels 102 and the structure 105. The first spacer material layer 110 may be comprised of a variety of materials, such as, for example, silicon nitride, silicon dioxide, etc. The thickness of the first spacer material layer 110 may vary depending upon the size of the features to be formed in the structure 105, as described more fully below.

In one illustrative embodiment, where the sacrificial mandrels 102 are comprised of silicon dioxide and the hard mask layer 103 is comprised of, for example, polysilicon, the first spacer material layer 110 may be a layer of silicon nitride and it may have a thickness of about 5-50 nm. In one particularly illustrative example, the thickness of the first spacer material layer 110 may be such that spacers formed from the first spacer material layer 110 will have a base thickness that is equal to or less than one-half of the pitch distance 106.

Next, as shown in FIG. 2C, an anisotropic etching process is performed on the first spacer material layer 110 to define a plurality of first sidewall spacers 110S on opposite sides of the sacrificial mandrels 102. In one illustrative embodiment, the width of each of the first sidewall spacers 110S may be about 5-50 nm or equal to or less than one-half of the pitch distance 106.

Then as shown in FIG. 2D, an etching process is performed to remove the sacrificial mandrels 102 selectively relative to the first sidewall spacers 110S and the hard mask layer 103. The process forms cavities 114 in the areas formerly occupied by the sacrificial mandrels 102.

Next as shown in FIG. 2E, a second spacer material layer 120 is conformably deposited above the first sidewall spacers 110S and the structure 105 and in the cavities 114. The second spacer material layer 120 may be comprised of a variety of materials, such as, for example, silicon nitride, silicon dioxide, etc. The thickness of the second spacer material layer 120 may vary depending upon the size of the features to be formed in the structure 105, as described more fully below. In one illustrative embodiment, where the hard mask layer 103 is comprised of, for example, polysilicon and the first sidewall spacers 110S are comprised of silicon nitride, the second spacer material layer 120 may be a layer of silicon dioxide and it may have a thickness of about 5-50 nm. In one particularly illustrative example, the thickness of the second spacer material layer 120 may be such that spacers formed from the second spacer material layer 120 will have a base thickness that is equal to or less than one-quarter of the pitch distance 106.

Next, as shown in FIG. 2F, an anisotropic etching process is performed on the second spacer material layer 120 to define a plurality of second sidewall spacers 120S on opposite sides of the first sidewall spacers 110S. In one illustrative embodiment, the width of each of the second sidewall spacers 120S may be about 5-50 nm or equal to or less than one-quarter of the pitch distance 106.

Then as shown in FIG. 2G, an etching process is performed to remove the first sidewall spacers 110S selectively relative to the second sidewall spacers 120S and the hard mask layer 103. The process forms a patterned spacer mask 126 comprised of the second sidewall spacers 120S.

Then, as shown in FIG. 2H, one or more etching processes are performed to transfer the pattern defined by the patterned spacer mask layer 126 to the hard mask layer 103 which thereby results in the definition of a patterned hard mask layer 103A. As noted above, the methods disclosed herein do not require the formation of the depicted patterned hard mask layer 103A in all applications. That is, in one embodiment, depending on the material of constructions, the pattern defined by the patterned spacer mask layer 126 may be transferred directly to an underlying structure or layer of material without the need of such a patterned hard mask layer 103A. Moreover, the patterned spacer mask layer 126 may be used in forming any type of feature on an integrated circuit product, e.g., gate electrodes, metal lines and vias, trenches, line-type features, hole-type feature, island-type feature, etc.

Next, as shown in FIG. 2I, in one illustrative embodiment, an etching process is performed to remove the patterned spacer mask layer 126. However, the patterned spacer mask layer 126 may not be removed in all applications.

FIG. 2K reflects the device 100 after an etching process, either a wet or dry etching process, has been performed on the substrate 101 through the patterned hard mask layer 103A to define a plurality of trenches 132 in the substrate 101. In one embodiment, the trenches 132 define a plurality of fins 134 for various FinFET transistors (not shown) that will be formed in and above the substrate 101. Of course, as noted above, the features formed using the methods disclosed herein can be any type of feature.

As will be appreciated by those skilled in the art after a complete reading of the present application, the methods disclosed herein will provide device designers with greater flexibility as it relates to the manufacturing of integrated circuit products wherein the size of various features of such products are smaller than the resolution capability of the photolithography process that will be used in forming such products.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
forming a sacrificial mandrel above a structure;
forming a plurality of first sidewall spacers on opposite sides of said sacrificial mandrel;
removing said sacrificial mandrel;
forming a plurality of second sidewall spacers on opposite sides of each of said first sidewall spacers, wherein forming said plurality of second sidewall spacers comprises exposing an upper surface of said structure between each of said plurality of first sidewall spacers; and
after forming said plurality of second sidewall spacers, removing said first sidewall spacers to thereby define a patterned spacer mask layer comprised of said plurality of second sidewall spacers.

2. The method of claim 1, further comprising performing an etching process on said structure through said patterned spacer mask layer.

3. The method of claim 1, wherein said structure is comprised of a layer of a material or a semiconducting substrate.

4. The method of claim 1, wherein forming said plurality of first sidewall spacers comprises:
depositing a layer of a first spacer material above said sacrificial mandrel; and
performing a first etching process on said layer of first spacer material to thereby define said plurality of first sidewall spacers.

5. The method of claim 4, wherein removing said sacrificial mandrel comprises performing a second etching process to remove said sacrificial mandrel.

6. The method of claim 5, wherein forming said plurality of second sidewall spacers comprises:
depositing a layer of a second spacer material above said plurality of first sidewall spacers; and
performing a third etching process on said layer of second spacer material to thereby define said plurality of second sidewall spacers.

7. The method of claim 6, wherein removing said plurality of first sidewall spacers comprises performing a fourth etching process to remove said plurality of first sidewall spacers.

8. The method of claim 1, wherein said first sidewall spacers and said second sidewall spacers have different thicknesses.

9. The method of claim 1, wherein said sacrificial mandrel is comprised of silicon dioxide, said first sidewall spacers are comprised of silicon nitride and said second sidewall spacers are comprised of silicon dioxide.

10. A method, comprising:
forming first and second sacrificial mandrels above a structure, said first and second mandrels having a spacing corresponding to a pitch distance;
forming a plurality of first sidewall spacers on opposite sides of each of said first and second sacrificial mandrels, wherein forming said plurality of first sidewall spacers comprises exposing an upper surface of said structure between said first and second sacrificial mandrels, each of said first sidewall spacers having a thickness that is equal to or less than one-half of said pitch distance;
removing said first and second sacrificial mandrels;
forming a plurality of second sidewall spacers on opposite sides of each of said first sidewall spacers, wherein forming said plurality of first sidewall spacers comprises exposing an upper surface of said structure between each of said plurality of first sidewall spacers, each of said second sidewall spacers having a thickness that is equal to or less than one-quarter of said pitch distance; and
after forming said plurality of second sidewall spacers, removing said first sidewall spacers to thereby define a patterned spacer mask layer comprised of said plurality of second sidewall spacers.

11. The method of claim 10, further comprising performing an etching process on said structure through said patterned spacer mask layer.

12. The method of claim 10, wherein said structure is comprised of a layer of a material or a semiconducting substrate.

13. The method of claim 10, wherein forming said plurality of first sidewall spacers comprises:
depositing a layer of a first spacer material above said first and second sacrificial mandrels; and
performing a first etching process on said layer of first spacer material to thereby define said plurality of first sidewall spacers.

14. The method of claim 13, wherein removing said first and second sacrificial mandrels comprises performing a second etching process to remove said first and second sacrificial mandrels.

15. The method of claim 14, wherein forming said plurality of second sidewall spacers comprises:
depositing a layer of a second spacer material above said plurality of first sidewall spacers; and
performing a third etching process on said layer of second spacer material to thereby define said plurality of second sidewall spacers.

16. The method of claim 15, wherein removing said plurality of first sidewall spacers comprises performing a fourth etching process to remove said plurality of first sidewall spacers.

17. The method of claim 10, wherein said first sidewall spacers and said second sidewall spacers have different thicknesses.

18. The method of claim 1, wherein said first sidewall spacers and said second sidewall spacers have different thicknesses.

19. The method of claim 1, wherein a thickness of said second sidewall spacers is less than approximately one-half of a thickness of said first sidewall spacers.

20. The method of claim 1, wherein said structure comprises a hard mask formed above a substrate.
